(19) United States
(12) Patent Application Publication
(10) Pub. No.: US 2014/0110690 A1
(43) Pub. Date: Apr. 24, 2014

(54) LIGHT EMITTING DEVICE AND DISPLAY DEVICE HAVING THE SAME

(71) Applicant: Samsung Display Co., Ltd., Yongin-City (KR)

(72) Inventors: Tadao YAGI, Yokohama (JP); Noriyuki MISHINA, Yokohama (JP); Ryuichi SATOH, Yokohama (JP); Hiroshi MIYAO, Yokohama (JP)

(73) Assignee: Samsung Display Co., Ltd., Yongin-City (KR)

(21) Appl. No.: 14/060,952

(22) Filed: Oct. 23, 2013

(30) Foreign Application Priority Data
Oct. 24, 2012 (JP) 2012-234655

(51) Int. Cl. H01L 51/52; H01L 27/32

(52) U.S. Cl. CPC H01L 51/5284; H01L 27/3295
USPC 257/40; 438/29

(57) ABSTRACT

A light emitting device includes a transparent substrate having an uneven surface, a black matrix on a predetermined area of the uneven surface of the transparent substrate, a first insulation layer on the transparent substrate and the black matrix, a thin film transistor on the first insulation layer, the thin film transistor corresponding to a position of the black matrix, a first electrode on the thin film transistor and electrically connected to the thin film transistor, an EL layer on the first electrode, and a second electrode on the EL layer.

### CROSS-REFERENCE TO RELATED APPLICATION

Japanese Patent Application No. 2012-234655, filed on Oct. 24, 2012, in the Korean Intellectual Property Office, and entitled: “LIGHT EMITTING DEVICE AND DISPLAY DEVICE HAVING THE SAME,” is incorporated by reference herein in its entirety.

### BACKGROUND

1. Field

Embodiments relate to a light emitting device and a display device including the light emitting device.

2. Description of the Related Art

In recent years, electroluminescence display devices (hereinafter, referred to as EL display device) have been developed as image display devices. The EL display device is different from a liquid crystal display device, and is a luminous type display device that implements a display by emitting light from a light emitting material, e.g., an organic compound in an emission layer, by recombining holes and electrons injected from an anode and a cathode into the emission layer. The emission layer between the cathode and anode may be a light emitting element (hereinafter, referred to as an EL element).

A conventional EL element, e.g., an organic EL element, may include an anode, a hole transport layer disposed on the anode, an emission layer disposed on the hole transport layer, an electron transport layer, and a cathode disposed on the electron transport layer. Holes are injected into the anode, and the injected holes are injected into the emission layer through the hole transport layer. Meanwhile, electrons are injected from the cathode, and the injected electrons are injected into the emission layer through the electron transport layer. The holes and electrons injected into the emission layer are recombined, so that excitons are generated within the emission layer. The EL element emits lights using light generated by radiative deactivation of the excitons. Also, the EL element is not limited to the above-described components, and various modifications or changes of the EL element may be made.

The EL element is roughly classified into an inorganic EL element using an inorganic material as an emission body of the emission layer and an organic EL element using an organic material as the emission body of the emission layer. Since both the inorganic EL element and the organic EL element include stacked materials having different refractive indexes, a radiation efficiency of light to the exterior may be lowered due to refraction at interfaces between stacked materials.

For example, a material used as an emission body in the inorganic EL element may have a very large refractive index, so the inorganic EL element may be significantly influenced by total refraction at the interface. Therefore, light extraction efficiency of actually emitted light to air in the inorganic EL element may be about 10% to about 20%. Also, in case of the inorganic EL element, a driving voltage is high and it is difficult to obtain blue light emission.

In another example, a material used as an emission body in the organic EL element may have a function separation type of stack structure that includes two layers, e.g., a hole transport layer and an emission layer, so that high emission brightness, e.g., more than about 1000 cd/m², may be obtained despite a low voltage, e.g., less than about 10 V. An example of a conventional bottom emission type organic EL element is illustrated in FIG. 1.

As illustrated in FIG. 1, an organic EL element 100 includes an anode 104 formed on a substrate 102 (e.g., a glass substrate, etc.) through a sputtering or resistance heating deposition method of a transparent conductive film (e.g., an ITO film, etc.), a hole transport layer 106 formed on the anode 104 through the resistance heating deposition method of N,N′-di-1-naphthyl-N,N′-diphenyl benzidine (hereinafter, referred to as NPD), an emission layer 108 formed on the hole transport layer 106 through the resistance heating deposition method of 8-Hydroxyquinoline Aluminum (hereinafter, referred to as Alq3), and a cathode 110 formed on the hole transport layer 106 through the resistance heating deposition method of a metal film (e.g., aluminum, etc.). When a DC voltage or a DC current is applied using the anode 104 of the organic EL element 100 as a positive terminal and the cathode 110 thereof as a negative terminal, holes are injected into the emission layer 108 through the hole transport layer 106, and electrons are injected into the emission layer 108 from the cathode 110. The holes and electrons are recombined in the emission layer 108, and a light-emitting phenomenon occurs when excitons generated through the recombination transition from an excited state to a ground state.

In the organic EL element 100, light generated from the emission layer 108 is output in all directions from the emission layer 108 and is radiated outside the organic EL element 100 through the hole transport layer 106, the anode 104, and the substrate 102. Alternatively, the light may be directed in a direction opposite to a light extraction direction (e.g., a substrate (102) direction), and is reflected by the cathode 110 to be radiated outside the organic EL element 100 through the emission layer 108, the hole transport layer 106, the anode 104, and the substrate 102.

However, in the event that a refractive index of a medium of an input side is larger than that of a medium of an output side when light passes through an interface of each medium, light incident at an angle having an output refracted angle of about 90 degrees, i.e., an angle larger than a critical angle, is totally reflected (rather than penetrating the interface). Thus, the light is not emitted outside the organic EL element 100.

In general, a relation between a refraction angle of light at an interface between different mediums, and a refractive index of the medium complies with Snell's law. In accordance with Snell's law, in the event that light progresses from a medium having a refractive index n1 to a medium having a refractive index n2, “n1 sin θ1=n2 sin θ2” is established between an incidence angle θ1 and a refraction angle θ2. Thus, in a case where n1>n2, the incidence angle θ1 (=Arcsin(n2/n1)), so θ2=90° is well known as a critical angle. If the incidence angle is larger than Arcsin(n2/n1), the light is totally reflected at the interface between the different mediums. Thus, in the organic EL element where the light is isotropically radiated, light radiated at an angle larger than the critical angle is totally reflected at the interface, and is locked, i.e., not emitted outside the organic EL element 100.

For example, in the event that a refractive index n of each of the hole transport layer 106 and the emission layer 108 of the organic EL element 100 is 1.7, a refractive index n of the anode 104 using ITO is 2.0, and a refractive index n of the substrate 102 using a glass is 1.5, a ratio of a wave-guided light (not extracted to the exterior) locked in the ITO or in the organic EL layer is about 45%, and a ratio of a wave-guided light (not extracted to the exterior) locked in the substrate is about 35%. Thus, as a ratio of a radiated light to a light (not extracted to the exterior) locked in each layer, about 20% of emitted light is extracted to the exterior.

### SUMMARY

Embodiments provide a light emitting device including a transparent substrate having an uneven surface, a black matrix on a predetermined area of the uneven surface of the transparent substrate, a first insulation layer on the transparent substrate and the black matrix, a thin film transistor on the first insulation layer, the thin film transistor corresponding to a position of the black matrix, a first electrode on the thin film transistor and electrically connected to the thin film transistor, an EL layer on the first electrode, and a second electrode on the EL layer.

An average roughness of the uneven surface may be more than 0.7 μm and less than 5 μm.

The first insulation layer may include a glass frit having a refractive index higher than 1.8.

The first insulation layer may have an even surface.

The EL layer may be an organic EL layer.

A display device having a display panel may include the light emitting device.

Embodiments provide a light emitting device including a transparent substrate, a black matrix on a predetermined area of the transparent substrate, a light scattering layer on the transparent substrate and the black matrix, the light scattering layer including a light scattering particle, a thin film transistor on the light scattering layer, the thin film transistor corresponding to a position of the black matrix, a first electrode on the thin film transistor and electrically connected to the thin film transistor, an EL layer on the first electrode, and a second electrode on the EL layer.

The light scattering layer may include a glass frit having a refractive index higher than 1.8, the light scattering particle in the light scattering layer having a size of about 0.5 μm to about 10 μm and a refractive index larger or smaller by more than 0.1 relative to a refractive index of the glass frit.

The EL layer may be an organic EL layer.

The display device may further include a polarization plate and a λ/4 retardation plate.

Embodiments provide a method of fabricating a light emitting device including forming an uneven surface on a surface of a transparent substrate, forming a black matrix on a predetermined area of the unevenness surface, forming a thin film transistor on the first insulation layer, the thin film transistor corresponding to a position of the black matrix, forming a first electrode on the thin film transistor and electrically connected to the thin film transistor, forming an EL layer on the first electrode, and forming a second electrode on the EL layer.

### BRIEF DESCRIPTION OF THE DRAWINGS

Features will become apparent to those of ordinary skill in the art by describing in detail exemplary embodiments with reference to the attached drawings, in which:

FIG. 1 illustrates an example of a conventional bottom emission type organic EL element;

FIG. 2 illustrates a diagram for describing functions of a polarization plate and a λ/4 retardation plate;

FIG. 3 illustrates a schematic view of a display panel according to an embodiment, where part (a) illustrates a top view of the display panel and part (b) illustrates an enlarged partial view of a pixel in part (a);

FIG. 4A illustrates a cross-sectional view of a pixel along line A-A in FIG. 3B;

FIG. 4B illustrates a cross-sectional view of a pixel according to another embodiment;

FIG. 5A illustrates a cross-sectional view of a pixel according to yet another embodiment;

FIG. 5B illustrates a cross-sectional view of a pixel according to still another embodiment;

FIG. 6 illustrates a diagram for measuring light extraction strength and reflection strength of an external light; and

FIGS. 7A-7D illustrate stages in a method of fabricating a light emitting device according to an embodiment.

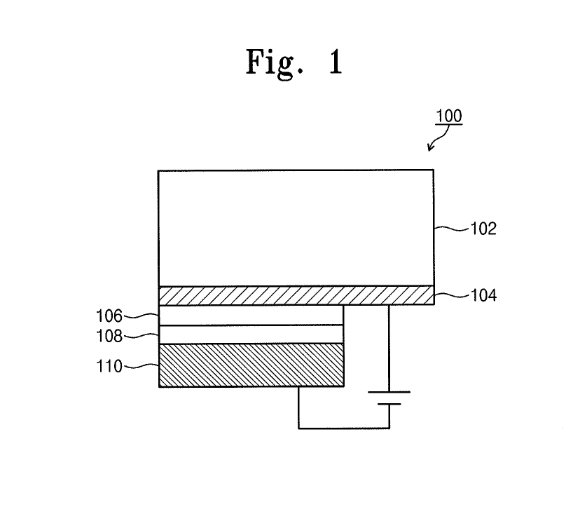

### DETAILED DESCRIPTION

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments will be explained in detail with reference to the accompanying drawings.

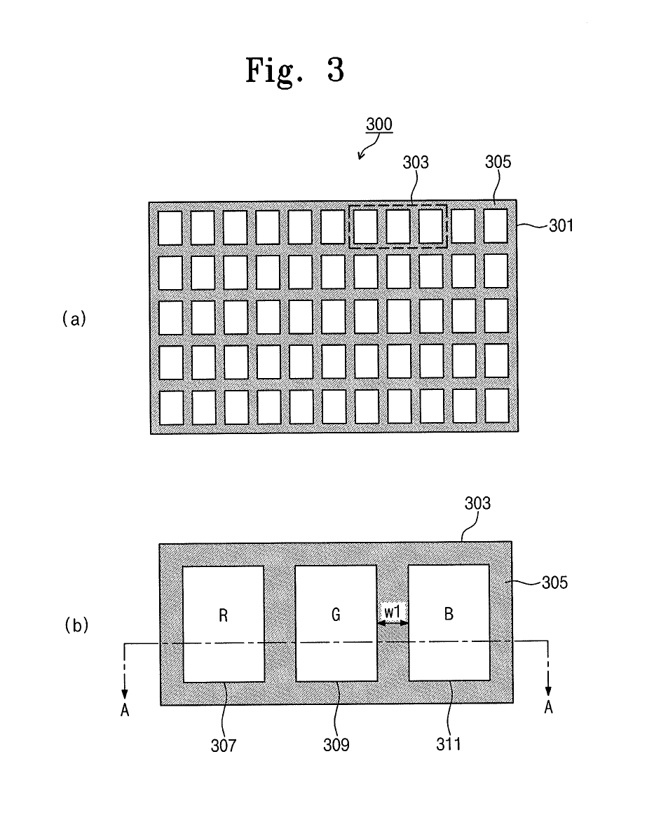

FIG. 3(a) is a top view of a display panel 301 of a display device 300 including a light emitting element according to embodiments. FIG. 3(b) is an enlarged diagram showing a pixel 303 (surrounded by a dotted line) shown in FIG. 3(a).

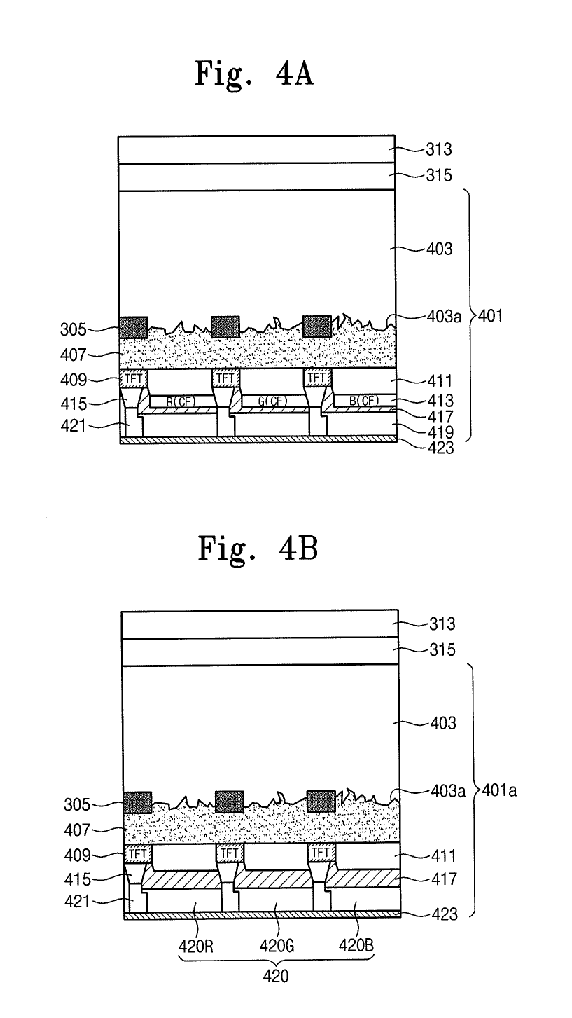

Referring to FIGS. 3(a) and 3(b), the display device 300 may include the display panel 301 with a plurality of pixels 303. An aperture ratio of each pixel 303 may be, e.g., about 50%. Each pixel 303 may include a red sub-pixel 307, a green sub-pixel 309, and a blue sub-pixel 311. Also, the display panel 301 may include a black matrix 305 that is disposed to surround each sub-pixel. A width w1 of the black matrix 305 between adjacent sub-pixels may be, e.g., about 55 μm. The display panel 300 may further include a polarization plate 313 and a λ/4 retardation plate 315 (FIG. 4A) disposed at a top of the display panel 301. For example, the λ/4 retardation plate 315 may be a λ/4 retardation film that is attached to the polarization plate 313.

A structure of the pixel 303 is not limited to the present disclosure. For example, the pixel 303 may further include a white sub-pixel in addition to the red sub-pixel 307, the green sub-pixel 309, and the blue sub-pixel 311. The white sub-pixel may be disposed when high brightness display requiring a peak brightness is necessary. Also, sizes and arrangements of the sub-pixels 307, 309, and 311 in the pixel 303 are not limited to the present disclosure. Further, a width w1 of the black matrix 305 disposed between sub-pixels may be changed to be suitable for a size of each sub-pixel.

FIG. 4A illustrates a structure of a light emitting device according to an embodiment. FIG. 4A is a cross-sectional view of the pixel 303 of the display panel 301 taken along line A-A in FIG. 3(b).

Referring to FIG. 4A, the pixel 303 may include a light emitting device 401 according to an embodiment. The light emitting device 401 may include a transparent substrate 403, the black matrix 305, a first insulation layer 407, a thin film transistor (TFT) 409, a second insulation layer 411, a color filter (CF) 413, an intermediate insulation layer 415, a transparent electrode 417, an organic EL layer 419, a bank 421, and a cathode 423. Also, the light emitting device 401 may include an inorganic EL layer instead of the organic EL layer 419 without limiting the above-described structure.

The transparent substrate 403 may have an uneven surface 403a on one surface. The transparent substrate 403 may be formed of a transparent material, e.g., a transparent plastic, etc., or of a glass, e.g., soda lime glass, alkali free glass, etc. The transparent plastic for forming the transparent substrate 403 may include insulation resin, e.g., polyethersulfone (PES), polyacrylate (PAR), polyetherimide (PEI), polyethylenenaphthalate (PEN), polyethyleneterephthalate (PET), polyphenylenesulfide (PPS), polyarylate, polyimide, polycarbonate (PC), cellulose triacetate (TAC), cellulose acetate propinonate (CAP), etc.

The uneven surface 403a of the transparent substrate 403 is a surface having a random unevenness and is facing the TFTs 409 and the organic EL layer 419. The uneven surface 403a generates light scattering of incident light, when light generated from the organic EL layer 419 is incident onto the transparent substrate 403 through the transparent electrode 417, the color filter 413, the second insulation layer 411, and the first insulation layer 407. In other words, the light generated from the organic EL layer 419 scatters when passing through the uneven surface 403a and iterates reflection in the light emitting element 401 several times. As a result, since the light is extracted to the exterior of the light emitting device 401, light extraction efficiency of the light emitting device 401 is improved. In the uneven surface 403a, an average surface roughness Ra of unevennesses may be more than 0.7 μm and less than 5 μm (based on JIS B 0601-2001 standards). If Ra of the uneven surface 403a exceeds 5 μm, planarization by the first insulation layer 407 may be difficult. Thus, since a roughness of a surface forming an electrode or an organic EL layer increases and a current is leaked, stable driving may be difficult. An unevenness shape of the uneven surface 403a is not limited to a particular shape, and may be, e.g., a pyramid shape, a lens shape, or a random shape.

The black matrix 305 is disposed on the uneven surface 403a of the transparent substrate 403. The black matrix 305 may be formed using, e.g., Cr₂O₃, TiN, Fe—Co—Mn materials, Cu—Fe—Mn materials, Mn—Sr materials, etc. For example, the black matrix 305 may be formed of a stack film of Cr₂O₃—Cr. The black matrix 305 absorbs light (external light) incident onto the light emitting element 401 from the exterior through the polarization plate 313 and the λ/4 retardation plate 315. In other words, the black matrix 305 may be on an opposite surface of the transparent substrate 403 relatively to the polarization plate 313 and the 214 retardation plate 315, so external light incident onto the light emitting element 401 from the exterior through the polarization plate 313 and the λ/4 retardation plate 315 may be absorbed in the black matrix 305 after being transmitted through the polarization plate 313, the λ/4 retardation plate, and the transparent substrate 403.

Conventionally, since an external light circularly polarized by a polarization plate and a λ/4 retardation plate passes through a light scattering surface, i.e., through an uneven surface, of a transparent substrate, a polarized light is in disorder to then become a scattered light to be incident onto a cathode. Since the polarized light is in disorder, the scattered light is incident on and reflected by the cathode back to pass through the polarization plate and the λ/4 retardation plate outside. Thus, external light is reflected outside, i.e., preventing reflection of an external light may be hindered.

In contrast, according to embodiments, since external light circularly polarized through the polarization plate 313 and the λ/4 retardation plate 315 is absorbed by the black matrix 305, an amount of scattered light progressing from the uneven surface 403a of the transparent substrate 403 toward the cathode 423 is reduced. That is, only a first portion of the external light incident onto the transparent substrate 403 is transmitted toward the cathode 423 from the uneven surface 403a as scattered light, as a second portion of the external light is absorbed by the black matrix 305. Therefore, a total amount of light output toward the cathode 423 from the uneven surface 403a as scattered light is reduced, e.g., as compared to a structure having no black matrix, so the amount of scattered light reflected by the cathode 423 toward the polarization plate 313 and the λ/4 retardation plate 315 is reduced. Therefore, overall reflection of external light may be substantially reduced.

As long as the black matrix 305 has sufficient thickness to absorb light, a film thickness of the black matrix 305 is not limited to a particular thickness. Also, the film thickness of the black matrix 305 may be variable according to a method of fabricating the film. For example, if the black matrix 305 is formed on the uneven surface 403a of the transparent substrate 403 by a sputtering method, the film thickness of the black matrix 305 may be about 100 nm to about 1000 nm. In another example, if the black matrix 305 is formed on the uneven surface 403a of the transparent substrate 403 by a glass binding method, the film thickness of the black matrix 305 may be about 1 μm to about 50 μm.

If a surface of a substrate is uneven, current may leak, so driving stability of a device may be reduced. Thus, the first insulation layer 407 having an even surface may be disposed on the uneven surface 403a of the transparent substrate 403 and on the black matrix 305.

A conventional organic EL element may include an anode (a transparent electrode (e.g., ITO, etc.) in a bottom emission type), an organic layer, and a cathode (a metal (e.g., aluminum) in a bottom emission type). The conventional organic layer may also include a hole transport layer, an emission layer, and an electron injection layer. The organic layer may be a thin film having film thickness of about 100 nm. If a flatness of the insulation layer 407 is low, the anode and cathode may be partially shorted, thereby indicating current leakage. For this reason, a surface roughness of the insulation layer 407 is less than 50 nm, e.g., less than 10 nm or less than 5 nm. The first insulation layer 407 may include a glass paste having glass fit, solvent, and resin, as a transparent material. The solvent may be a high boiling solvent, e.g., a terpene solvent (e.g., terpineol, etc.) or a carbitol solvent (e.g., butyl carbitol acetate, etc.). The resin may be a thickening binder resin, e.g., an acrylic resin or a cellulose resin (e.g., ethyl cellulose).

A refractive index of the glass frit, i.e., a material of the first insulation layer 407, may be equal to that of the transparent electrode 417 (e.g., formed of ITO) to be described later. In the event that a refractive index of the first insulation layer 407 is equal to that of the transparent substrate 403, reflection at an interface with the transparent electrode 417 is the same as if an interface between the uneven surface 403a and the first insulation layer 407 does not exist, i.e., so improvement of light extraction efficiency is not expected. For example, the transparent electrode 417 may be formed using ITO having a refractive index n of 2, and the glass fit constituting the first insulation layer 407 may have a refractive index n of more than 1.8.

Also, the glass frit used for the first insulation layer 407 exhibits thermal characteristics, e.g., the glass frit, i.e., the first insulation layer 407, is formed at a predetermined temperature on the transparent substrate 403 without causing twisting or deformation thereof. In detail, since a conventional glass substrate (e.g., soda lime glass) used for the transparent substrate 403 is twisted or changed at a temperature higher than 500° C., a glass transition temperature Tg of the glass frit for the first insulation layer 407 is lower than 450° C., e.g., lower than 400° C. Examples of glass fit having a low glass transition temperature and/or a high refractive index may include P₂O₅, SiO₂, B₂O₃, Ge₂O, and/or TeO₂ as a network former and TiO₂, Nb₂O₅, WO₃, Bi₂O₃, La₂O₃, Gd₂O₃, Y₂O₃, ZrO₂, ZnO, BaO, PbO, and/or Sb₂O₃ as a high refractive index of component. Also, in addition to the above-described components, alkali metal oxide, alkali earth metal oxide, fluoride, etc. may be used as a component of the glass frit to adjust a characteristic of the glass, within a range where a property of matter required for a refractive index is not damaged. In some cases, also, an additional agent may be added to improve dispersive characteristic of the glass fit and resin or to adjust rheology.

The first insulation layer 407 may be formed by depositing, drying and burning the glass paste, formed by mixing the above-described materials, i.e., the glass fit, the solvent, and the binder resin, on the transparent substrate 403. A detailed description of the first insulation layer 407 is disclosed in JP Publication No. 2012-133944 incorporated herein by reference.

The thin film transistor 409 and the second insulation layer 411 are disposed on the first insulation layer 407. The thin film transistor 409 is formed at an area corresponding to, e.g., overlapping, the black matrix 305. Also, although not shown, a wiring layer may be formed on the first insulation layer 407. Red, green, and blue color filters 413 are disposed on the second insulation layer 411 to correspond to a red sub-pixel 307, a green sub-pixel 309, and a blue sub-pixel 311 of the pixel 303, respectively. The transparent electrode 417 is formed on the color filter (CF) 413, and is electrically connected to each TFT 409 through each contact hole formed at the intermediate insulation layer 415 that is formed on the TFT 409.

A refractive index of the second insulation layer 411 is equal to or larger than that of the first insulation layer 407. For example, SiN_{X} or SiO₂ formed by a sputtering method or a CVD method may be used as the insulation layer 411. Thus, it is possible to efficiently extract a wave-guided light of a thin film locked in the transparent electrode 417 and the organic EL layer 419 to the exterior.

However, embodiments are not limited thereto when the color filter CF is formed. That is, since a refractive index of a conventional CF material is about 1.5 to about 1.6, it may be difficult to extract a wave-guided light of a thin film locked in the transparent electrode 417 and the organic EL layer 419 when the CF is formed.

The transparent electrode 417 functions as an anode of the light emitting device 401. The transparent electrode 417 has conductivity and is formed of a transparent material for extracting light to the outside of the light emitting device 401. For example, ITO, IZO(InZnO), ZnO, In₂O₃, etc. may be used as a material of the transparent electrode 417. A current corresponding to each of sub-pixels 307, 309, and 311 is applied to the transparent electrode 417.

The organic EL layer 419 for generating a white light is formed on the transparent electrode 417. The organic EL layer 419 includes an emission layer. In some cases, the organic EL layer 419 may include a hole injection layer, a hole transport layer, an electron injection layer, an electron transport layer, etc. Each layer forming the organic EL layer 419 may be used any suitable material. The organic EL layer 419 is partitioned by a bank 421 disposed on the intermediate insulation layer 415 to correspond to the sub-pixels 307, 309, and 311, respectively.

The cathode 423 is disposed on the organic EL layer 419. A metal is used as a material forming the cathode 423. For example, Ag, Mg, Al, Pt, Pd, Au, Ni, Nd, Ir, Cr, Li, Ca, and/or a compound thereof may be used as a material forming the cathode 423.

As described above, the light emitting device 401 according to an embodiment may include the black matrix 305 on the uneven surface 403a of the transparent substrate 403, so that external light transmitted through the polarization plate 313, the λ/4 retardation plate 315, and the transparent substrate 403 to be incident on the uneven surface 403a of the transparent substrate 403 is absorbed by the black matrix 305 before scattering. Therefore, external light reflected by the cathode 423, after being scattered by the uneven surface 403a of the transparent substrate 403, is reduced. Further, since the uneven surface 403a is formed on the transparent substrate 403 and light generated by the organic EL layer 419 is scattered at the uneven surface 403a, light extraction efficiency of the light emitting device 401 is improved.

FIG. 4B is a cross-section view of a pixel of a display panel according to another embodiment. Referring to FIG. 4B, the pixel includes a light emitting device 401a. In FIG. 4B, elements that are the same as those shown in FIG. 4A are marked by the same reference numerals.

As illustrated in FIG. 4B, the light emitting device 401a may include the transparent substrate 403, the black matrix 305, the first insulation layer 407, the thin film transistor (TFT) 409, the second insulation layer 411, the intermediate insulation layer 415, the transparent electrode 417, an organic EL layer 420, the bank 421, and the cathode 423. The light emitting device 401a is substantially the same as the light emitting device 401 in FIG. 4A, except that a color filter CF is omitted and the organic EL layer 20 is different from the organic EL layer 419 in FIG. 4A. Thus, a duplicate description of same elements as those of the light emitting device 401 is omitted.

The organic EL layer 420 of the light emitting device 401a in FIG. 4B includes a red organic EL layer 420R, a green organic EL layer 420G, and a blue organic EL layer 420B respectively corresponding to the red sub-pixel 307, the green sub-pixel 309, and the blue sub-pixel 311 of the pixel. The red organic EL layer 420R, the green organic EL layer 420G, and the blue organic EL layer 420B are separated by the bank 421. The red organic EL layer 420R has a red light-emitting layer, the green organic EL layer 420G has a green light-emitting layer, and the blue organic EL layer 420B has a blue light-emitting layer. The light emitting materials forming the red light-emitting layer, the green light-emitting layer, and the blue light-emitting layer may be any suitable materials. In the light emitting device 401a shown in FIG. 4B, since the organic EL layer 420 includes the red organic EL layer 420R, the green organic EL layer 420G, and the blue organic EL layer 420B, the color filter CF of the light emitting device 401 4A is omitted.

Like the light emitting device 401 shown in FIG. 4A, since the uneven surface 403a is formed on the transparent substrate 403 and light generated from the organic EL layer 420 is scattered, light extraction efficiency of the light emitting device 401a shown in FIG. 4B is improved. Also, reflection of the external light is suppressed by disposing the black matrix 305 on the uneven surface 403a of the transparent substrate 403. Further, in the light emitting device 401a, the organic EL layer 420 includes the red organic EL layer 420R, the green organic EL layer 420G, and the blue organic EL layer 420B, so light is emitted toward the transparent substrate 403 from the organic EL layer 420 without using a color filter, thereby using a lower driving voltage, e.g., as compared to the light emitting device 401.

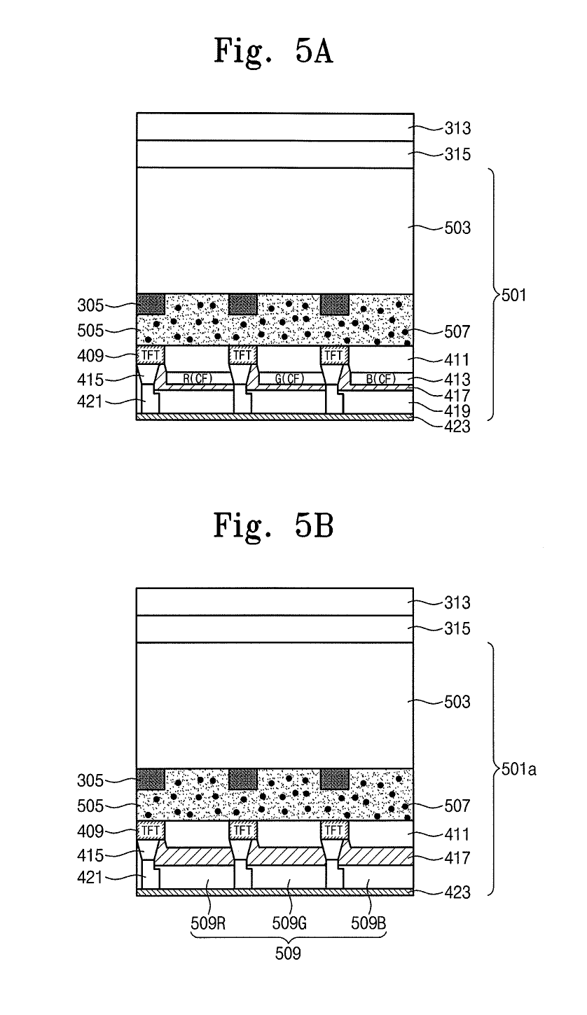

FIGS. 5A and 5B are cross-sectional views of a pixel of a display panel taken according to other embodiments. In FIGS. 5A and 5B, elements that are the same as those shown in FIG. 4A are marked by the same reference numerals.

Referring to FIG. 5A, a pixel may include a light emitting device 501. The light emitting device 501 may include a transparent substrate 503, the black matrix 305, a light scattering layer 505, the thin film transistor (TFT) 409, the second insulation layer 411, the intermediate insulation layer 415, the color filter (CF) 413, the transparent electrode 417, the organic EL layer 419, the bank 421, and the cathode 423. The light emitting device 501 is substantially the same as that shown in FIG. 4A, except that the light scattering layer 505 is included instead of a first insulation layer and an uneven surface of a transparent substrate. Thus, a duplicate description of same elements as those of the light emitting device 401 is omitted.

The light emitting device 501 has the transparent substrate 503. Like the transparent substrate 403 of the light emitting device 401 shown in FIG. 4A, the transparent substrate 503 may be formed of a transparent material, e.g., a transparent plastic, etc. or a glass, e.g., soda lime glass, alkali free glass, etc. Like the transparent substrate 403, the plastic for forming the transparent substrate 503 may use insulation resin, e.g., polyethersulfone (PES), polyacrylate (PAR), polyetherimide (PEI), polyethylenenaphthalate (PEN), polyethyleneterephthalate (PET), polyphenylenesulfide (PPS), polyarylate, polyimide, polycarbonate (PC), cellulose triacetate (TAC), cellulose acetate propinonate (CAP), etc. Unlike the transparent substrate 403 of the light emitting device 401, a surface of the transparent substrate 503 of the light emitting device 501 is even, i.e., substantially flat without roughness. The black matrix 305 is disposed on the transparent substrate 503.

The light scattering layer 505 is disposed on the transparent substrate 503 and the black matrix 305. That is, the light scattering layer 505 is disposed between the transparent substrate 503 and the second insulation layer 411 and covers the black matrix 305. The light scattering layer 505 has an even surface and is formed of a transparent material. The light scattering layer 505 includes a glass paste having glass frit, solvent, binder resin, and a light scattering particle 507 for scattering light. Like the glass frit of the first insulation layer 407 of the light emitting device 401, a refractive index n of the glass frit of the light emitting layer 505 is higher than 1.8 when the transparent electrode 417 is formed using ITO with the refractive index of 2. A glass transition temperature Tg of the glass frit of the light emitting layer 505 is lower than 450° C., e.g., lower than 400° C. The glass fit, the solvent, and the binder resin of the light emitting layer 505 may be formed of the same materials as those of the first insulation layer 407 of the light emitting device 401.

A shape of the light scattering particle 507 is not limited to a particular shape. For example, the shape of the light scattering particle 507 may be an indeterminate shape or a complete globular shape. The size, e.g., diameter, of the light scattering particle 507 may be about 0.5 μm to about 10 μM, e.g., about 1 μm to about 2 μm. A refractive index of the light scattering particle 507 is higher or lower by more than 0.1 than that of the glass frit included in the light scattering layer 505, e.g., a refractive index of the light scattering particle 507 is higher or lower by more than 0.3 than that of the glass frit included in the light scattering layer 505. In other words, a ratio between the refractive indexes of the light scattering particle 507 and the glass frit included in the light scattering layer 505 is higher than 0.1, e.g., higher than 0.3. Examples of material used for the light scattering particle 507 may include an inorganic oxide, e.g., SiO₂, Al₂O₃, TiO₂, etc., an organic filler, e.g., Mg₂Al₃(AlSi₅O₁₈)(Cordierite), β-LiAlSi₂O₆ ((β-spodumene), ZrSiO₄ (Zircon), ZrW₂O₈, (ZrO)₂P₂O₇, KZr₂(PO₄)₃, Zr₂(WO₄)(PO₄)₂, etc.

Unlike the light emitting device 401 shown in FIG. 4A, the light emitting device 501 according to an embodiment has the light scattering layer 505 with the light scattering particle 507, instead of forming an uneven surface on a transparent substrate for scattering light. If light generated by the organic EL layer 419 is transmitted toward the light scattering layer 505 through the transparent electrode 417, the color filter 413, and the second insulation layer 411, the light incident onto the light scattering layer 505 is incident onto a surface of the light scattering particle 507 and then scattered. The light generated by the organic EL layer 419 is scattered via the light scattering particle 507 whenever it passes through the light scattering layer 505, and iterates reflection within the light emitting device 501 several times. Since light is extracted into the outside of the light emitting device 501, light extraction efficiency of the light emitting device 501 is improved.

The light emitting device 501 according to an embodiment includes the black matrix 305 on the transparent substrate 503, so that an external light incident through the polarization plate 313 and the λ/4 retardation plate 315 passes through the light scattering layer 505 and then is absorbed by the black matrix 305 at the light scattering layer 505 before scattering. Therefore, reflection of external light by the cathode 423, after passing through the light scattering layer 505 and then being scattered, is reduced. Further, since the light scattering layer 505 including the light scattering particle 507 is formed and a light generated by the organic EL layer 419 is scattered by the light scattering particle 507, light extraction efficiency of the light emitting device 501 is improved.

FIG. 5B is a cross-section view of a pixel of a display panel according to another embodiment. Referring to FIG. 5B, a pixel may include a light emitting device 501a. The light emitting device 501a includes the transparent substrate 503, the black matrix 305, the light scattering layer 505, the thin film transistor (TFT) 409, the second insulation layer 411, the intermediate insulation layer 415, the transparent electrode 417, an organic EL layer 509, the bank 421, and the cathode 423. The light emitting device 501a is substantially the same as that shown in FIG. 5A, except that a color filter CF is omitted and the organic EL layer 509 is different from that shown in FIG. 5A. Thus, a duplicate description of same elements as those of the light emitting device 501 is omitted.

Like the light emitting device 401a shown in FIG. 4B, the organic EL layer 509 of the light emitting device 501a shown in FIG. 5B includes a red organic EL layer 509R, a green organic EL layer 509G, and a blue organic EL layer 509B respectively corresponding to a red sub-pixel 307, a green sub-pixel 309, and a blue sub-pixel 311 of the pixel. The red organic EL layer 509R, the green organic EL layer 509G, and the blue organic EL layer 509B are separated by the bank 421. The red organic EL layer 509R has a red light-emitting layer, the green organic EL layer 509G has a green light-emitting layer, and the blue organic EL layer 509B has a blue light-emitting layer. Any suitable materials may be used as light emitting materials forming the red light-emitting layer, the green light-emitting layer, and the blue light-emitting layer. In the light emitting device 501a shown in FIG. 5B, since the organic EL layer 509 includes the red organic EL layer 509R, the green organic EL layer 509G, and the blue organic EL layer 509B, the color filter CF of the light emitting device 501 shown in FIG. 5A is omitted.

Like the light emitting device 501 shown in FIG. 5A, according to the light emitting device 501a, since the light scattering layer 505 including the light scattering particle 507 is disposed and a light generated by the organic EL layer 419 is scattered, light extraction efficiency of the light emitting device 501a is improved. Also, reflection of the external light is suppressed by disposing the black matrix 305 on the transparent substrate 503. Also, in the light emitting device 501a, the organic EL layer 509 includes the red organic EL layer 509R, the green organic EL layer 509G, and the blue organic EL layer 509B, and light is output toward the transparent substrate 503 from the organic EL layer 509 without passing through the color filter. Therefore, the light emitting device 501a is driven using a lower voltage as compared to the light emitting device 401.

### EXAMPLES

The light emitting devices 401, 401a, 501, and 501a are fabricated, so light extraction strength and reflection strength thereof can be measured. Herein, the light emitting device 401 is referred to as a first example, the light emitting device 401a is referred to as a second example, the light emitting device 501 is referred to as a third example, and the light emitting device 501a is referred to as a fourth example.

As a first comparative example, a light emitting device is fabricated to be substantially the same as the light emitting devices 401, with the exception of removing the uneven surface 403a of the transparent substrate 403, the black matrix 305, and the first insulation layer 407, so the thin film transistor (TFT) 409 and the second insulation layer 411 are formed on an even surface of a transparent substrate 403. As a second comparative example, a light emitting device is fabricated to be substantially the same as the light emitting devices 401, with the exception of removing the black matrix 305. As a third comparative example, a light emitting device is fabricated to be substantially the same as the light emitting devices 401a, with the exception of removing the uneven surface 403a of the transparent substrate 403, the black matrix 305, and the first insulation layer 407, so the thin film transistor (TFT) 409 and the second insulation layer 411 are formed on an even surface of a transparent substrate 403. As a fourth comparative example, a light emitting device is fabricated to be substantially the same as the light emitting devices 501a, with the exception of removing the black matrix 305.

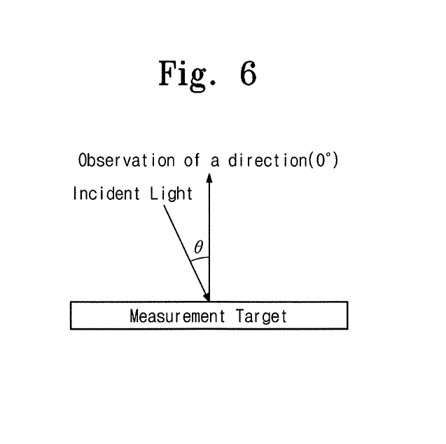

As illustrated in FIG. 6, the reflection strength is measured on the basis of relative reflection strength of a light incident with an angle θ of 30° with respect to observation of a direction (0°).

In each example and each comparative example, an aperture ratio of a pixel is almost 50%. Results are shown in the following tables 1 and 2. Also, in measurement of light extraction strength and reflection strength of an external light of a display panel of each example and each comparative example, the first and third examples and the first and second comparative examples, i.e., where a light emitting device is fabricated including a color filter CF, form a first group, and the second and fourth examples and the third and fourth comparative examples, i.e., where a light emitting device is fabricated without the color filter CF, form a second group. The light extraction strength and the reflection strength of an external light are measured by a group unit.

The light extraction strength is compared by lighting all of RGB under the same driving condition for a white color and measuring a surface luminance using CA2000 of the Konica Minolta Company. Also, the reflection strength of an external light is measured using a variable angle photometer GP-700 of the Murakami color Company. SEG1425DU of the NITTO DENKO Company is used as a polarization plate, and WRF-S-148 of the Teijin Chemicals Company is used as a λ/4 retardation plate. In the light extraction strength and the relative reflection strength of each example and each comparative example, the light extraction strengths and the reflection strengths of the first and third comparative examples are used as a reference. In the first and third examples and the first and second comparative examples, a film thickness of a white emission layer (forming a layer) of the first comparative example is fabricated by a component of a light emitting device where the extraction strength (a device characteristic) becomes highest, and a film thickness of a white emission layer (forming a layer) of the first and third examples is fabricated by the same component.

In the second and fourth examples and the third and fourth comparative examples, a film thickness of each of R, G and B emission layers of the third comparative example is fabricated by a component of a light emitting device where the extraction strength (a device characteristic) becomes highest, and a film thickness (forming a layer) of the second and fourth embodiments is fabricated by the same component.

TABLE 1

| | Light extraction strength | Relative reflection strength |
|---|---|---|
| Example 1 | 1.3 | 1.4 |
| Example 3 | 1.2 | 1.5 |
| Comp. Ex. 1 | 1.0 | 1.0 |
| Comp. Ex. 2 | 1.3 | 13.7 |

TABLE 2

| | Light extraction strength | Relative reflection strength |
|---|---|---|
| Example 2 | 1.3 | 1.7 |
| Example 4 | 1.6 | 1.9 |
| Comp. Ex. 3 | 1.0 | 1.0 |
| Comp. Ex. 4 | 1.5 | 20.5 |

Table 1 shows a result of a display panel having a white emission layer to which a color filter CF is attached. Table 2 shows a result of a display panel having an RGB emission layer without a color filter CF.

As shown in Table 1, in a light emitting device including a color filter CF and a white emission layer according to embodiments, reflection of external light is reduced to be less than two times of that of a comparative light emitting device (the first comparative example) that does not include a light scattering surface or a light scattering layer, and light extraction efficiency is improved by 1.2 to 1.3 times. In addition, in case of a light emitting device (the second comparative example) to which a light scattering surface is attached and which does not include a black matrix, the light extraction efficiency is scarcely changed, and the reflection of the external light is increased by more than 13 times. Thus, it is understood that the light emitting device (the second comparative example) is not suitable for a display device.

As shown in the table 2, in a light emitting device including a color filter CF and including a red light emitting layer, a green light emitting layer, and a blue light emitting layer according to embodiments, reflection of an external light is reduced to be less than two times of that of a comparative light emitting device (the third comparative example) that does not include a light scattering surface or a light scattering layer, and light extraction efficiency is improved by 1.6 to 1.7 times. In addition, in case of a light emitting device (the fourth comparative example) to which a light scattering surface is attached and which does not include a black matrix, the light extraction efficiency is scarcely changed, and the reflection of the external light is increased by more than 20 times. Thus, it is understood that the light emitting device (the fourth comparative example) is not suitable for a display device.

According to the above results, a light emitting device according to embodiments suppresses the reflection of external light, improves the light extraction efficiency, and is suitable for a display device. Also, while an organic EL element having an organic EL layer is described as a light emitting device according to an embodiment, an inorganic EL element having an inorganic EL layer may be used instead of an organic EL layer. That is, in the inorganic EL element, like in the organic EL element, the reflection of the external light is suppressed and the light extraction efficiency is improved by including a black matrix formed on a transparent substrate or an unevenness surface (light scattering surface) or a light scattering layer formed on the transparent substrate.

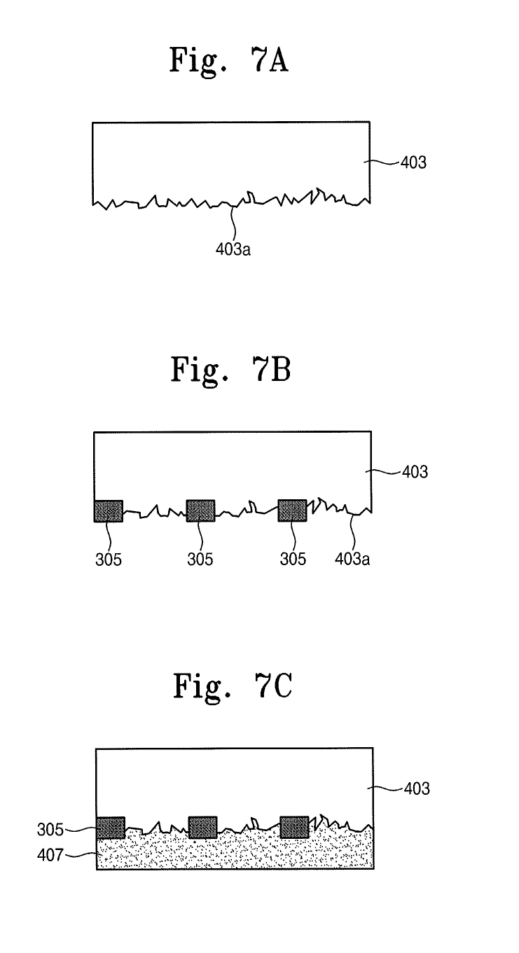

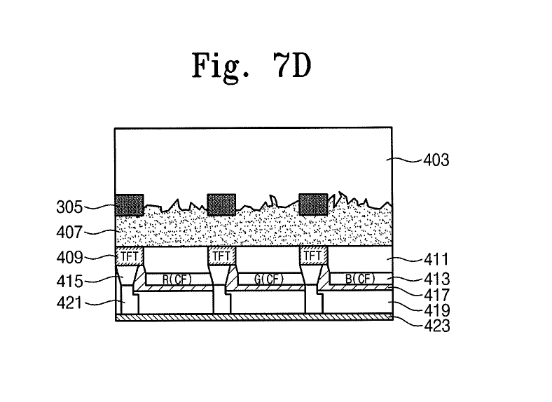

A method of fabricating the light emitting device 401 according to an embodiment is described with reference to FIGS. 7A to 7D. Also, it is assumed that a glass substrate having a refractive index n of 1.5 is used as a transparent substrate 403.

First, as illustrated in FIG. 7A, the glass substrate 403 having a thickness of about 0.5 mm to about 1.0 mm is prepared. The uneven surface 403a is formed by grinding one surface of the glass substrate 403 using a sandblasting method or a wet etching method so as to have an average surface roughness Ra that is more than 0.7 μm and less than 5 μm.

Then, as illustrated in FIG. 7B, a black matrix layer is formed on the uneven surface 403a, so the black matrix 305 is formed at a predetermined area through patterning. The black matrix layer may be formed using a sputtering method or a glass binding method. In case of the glass binding method, the black matrix layer is formed by mixing a low melting glass as a binder and a material of the black matrix, coating a paste state of mixture on the uneven surface 403a and sintering a resultant structure. In the event that the black matrix 305 is formed using the sputtering method, a film thickness of the black matrix 305 may be about 100 nm to about 1000 nm. In the event that the black matrix 305 is formed using the glass binding method, a film thickness of the black matrix 305 may be about 1 μm to about 50 μm.

As shown in FIG. 7C, the first insulation layer 407 is formed on the unevenness surface 403a and the black matrix 305 to have a film thickness of about 3 μm to about 100 μm. The first insulation layer 407 is formed by coating the above-described glass paste on the glass substrate 403 and the black matrix 305, driving a solvent at about 100° C., and sintering a resultant structure at a temperature less than about 650° C.

Then, a thin film transistor (TFT) 409 is formed on an area of the first insulation layer 407 corresponding to the black matrix 305. Also, a second insulation layer 411 having a film thickness of about 1 μm to about 2 μm is formed on an area except for an area where the thin film transistor 409 is formed, and a color filter (CF) 413 is formed on a resultant structure. Afterwards, the intermediate insulation layer 415 is formed, and the transparent electrode 417 having a film thickness of about 50 nm to about 200 nm is formed so as to be electrically connected to the thin film transistor 409 through a contact hole formed in the intermediate insulation layer 415.

The organic EL layer 419 having a film thickness of about 50 nm to about 200 nm is formed on the transparent electrode 417, and the bank 421 for partitioning the organic EL layer 419 into sub-pixels is formed on the intermediate insulation layer 415. The cathode 423 having a film thickness of about 50 nm to about 200 nm is formed on the organic EL layer 419 and the bank 421. Methods of forming the thin film transistor 409, the second insulation layer 411, the color filter 413, the intermediate insulation layer 415, the transparent electrode 417, the organic EL layer 419, the bank 421, and the cathode 423 may be any suitable methods.

The light emitting device 401 according to embodiments may be fabricated by the above-described fabricating process. With the light emitting device, reflection of external light is suppressed, light extraction efficiency is improved, and a display device including the light emitting device is provided.

Conventionally, in order to improve light extraction efficiency, attempts have been made to convert an incidence angle onto a substrate of the organic EL element. For example, when fabricating a diffraction grid structure on a substrate, reflection of light having a particular wave length is prevented and extraction efficiency is improved. In another example, the same effect is obtained by adopting a lens structure on a substrate surface. However, such methods are effective to improve the extraction efficiency, while they necessitate a construction of an additional complicated fine structure. Thus, it may be difficult to apply such methods to a fabricating process.

For example, attempts have been made to improve extraction efficiency by dissipating a wave-guided light of a thin film using a special glass component having a same refractive index as that of a transparent conductive film used in the organic EL element. In the event that a structure (e.g., a lens, etc.) is prepared at an output side of a light opposite to the organic EL layer of the substrate, a wave-guided light of the thin film still remains in the layer and is not output. However, while extraction efficiency via the wave-guided light may be successful with a thin film, a substrate having a special high refractive index may require very high costs for commercial mass production, and may be problematic in terms of a practical use.

In another example, attempts have been made to reduce a wave-guided light of a thin film by forming and inserting a structure between a substrate and a transparent conductive film (e.g., an ITO, etc.) so as to change a refractive index by a diffraction grid or a scattering structure. In this case, since it is difficult to directly fabricate a transparent electrode film to correspond to a structure on the substrate, a material surface needs to be leveled using a material having the same refractive index as that of the transparent electrode. For example, an inorganic EL element may be fabricated by smoothing a substrate surface using a spin on grass (SOG) material on a substrate having random unevenness as a substrate of the inorganic EL element. In another example, SiN with a high refractive index may be fabricated as a film having a thickness of about 0.4 μm to about 2 μm on a substrate having a surface roughness Ra (e.g., about 0.01 μm to about 0.6 μm) using a CVD (Chemical Vapor Deposition) method, followed by fabricating an organic EL element using it as a substrate material, and reducing a wave-guided light of a thin film, and improving light extraction efficiency. In yet another example, a glass frit material that is melted at a high temperature may be used as a planarization layer having a high refractive index with the same constitution. In yet another example of a method of reducing a wave-guided light of a thin film, a high refractive index of glass layer may be formed, including a scattering component (e.g., an air, etc.), between an ITO and a substrate.

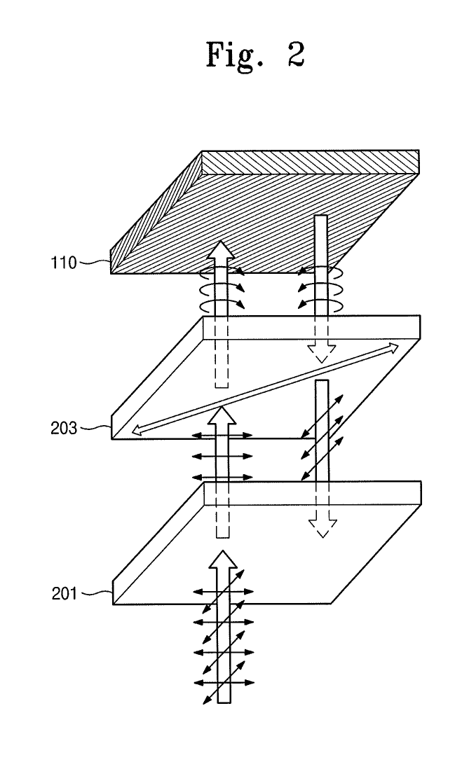

Further, as illustrated in FIG. 2, in order to improve contrast of a displayed image, an EL display device using an EL element requires a polarization plate 201 and/or a 214 retardation plate 203 to suppress reflection of an external light from a cathode 110 formed of aluminum, silver, etc. However, when a polarization plate and/or a 214 retardation plate for preventing reflection of the external light is applied to conventional EL elements in the above previously attempted examples, a polarized light may be in disorder at a portion of a light scattering surface scattering progress of light, a reflection preventing function may be reduced due to the polarization plate and λ/4 retardation plate for improving light extraction efficiency of an element, contrast of the display may be difficult to secure, and indoor and outdoor image visibilities may be problematic.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A light emitting device, comprising:
a transparent substrate having an uneven surface;
a black matrix on a predetermined area of the uneven surface of the transparent substrate;
a first insulation layer on the transparent substrate and the black matrix;
a thin film transistor on the first insulation layer, the thin film transistor corresponding to a position of the black matrix;
a first electrode on the thin film transistor and electrically connected to the thin film transistor;
an EL layer on the first electrode; and
a second electrode on the EL layer.

2. The light emitting device as claimed in claim 1, wherein an average roughness of the uneven surface is more than 0.7 μm and less than 5 μm.

3. The light emitting device as claimed in claim 1, wherein the first insulation layer includes a glass frit having a refractive index higher than 1.8.

4. The light emitting device as claimed in claim 1, wherein the first insulation layer has an even surface.

5. The light emitting device as claimed in claim 1, wherein the EL layer is an organic EL layer.

6. A display device having a display panel including a light emitting device as claimed in claim 1.

7. A light emitting device, comprising:
a transparent substrate;
a black matrix on a predetermined area of the transparent substrate;
a light scattering layer on the transparent substrate and the black matrix, the light scattering layer including a light scattering particle;
a thin film transistor on the light scattering layer, the thin film transistor corresponding to a position of the black matrix;
a first electrode on the thin film transistor and electrically connected to the thin film transistor;
an EL layer on the first electrode; and
a second electrode on the EL layer.

8. The light emitting device as claimed in claim 7, wherein the light scattering layer includes a glass fit having a refractive index higher than 1.8, the light scattering particle in the light scattering layer having a size of about 0.5 μm to about 10 μm and a refractive index larger or smaller by more than 0.1 relative to a refractive index of the glass frit.

9. The light emitting device as claimed in claim 7, wherein the EL layer is an organic EL layer.

10. The display device as claimed in claim 9, further comprising a polarization plate and a μ/4 retardation plate.

11. A method of fabricating a light emitting device, the method comprising:
forming an uneven surface on a surface of a transparent substrate;
forming a black matrix on a predetermined area of the unevenness surface;
forming a thin film transistor on the first insulation layer, the thin film transistor corresponding to a position of the black matrix;
forming a first electrode on the thin film transistor and electrically connected to the thin film transistor;
forming an EL layer on the first electrode; and
forming a second electrode on the EL layer.
